(19) United States
(12) Patent Application Publication
(10) Pub. No.: US 2026/0316439 A1
(43) Pub. Date: Oct. 15, 2026

(54) METHOD FOR PEELING OBJECT FROM ADHESIVE SHEET

(71) Applicant: LINTEC Corporation, Tokyo (JP)

(72) Inventors: Kenta NISHIJIMA, Tokyo (JP); Haruki SUEYOSHI, Tokyo (JP); Go ONISHI, Tokyo (JP); Tomofumi KATO, Tokyo (JP); Takashi SUGINO, Tokyo (JP); Mutsumi MASUMOTO, Beppu-shi, Oita (JP)

(21) Appl. No.: 19/113,687

(22) PCT Filed: Sep. 21, 2023
(86) PCT No.: PCT/JP2023/034246

§ 371 Date: Mar. 20, 2025

(30) Foreign Application Priority Data
Sep. 22, 2022 (JP) 2022-151756
Sep. 22, 2022 (JP) 2022-151757
Mar. 31, 2023 (JP) 2023-058459
Mar. 31, 2023 (JP) 2023-058460
Mar. 31, 2023 (JP) 2023-058462
Mar. 31, 2023 (JP) 2023-058463

(51) Int. Cl. B32B 43/00

(52) U.S. Cl. CPC B32B 43/006

(57) ABSTRACT

There is provided a pressure sensitive adhesive sheet from which an element is more easily peeled. The pressure sensitive adhesive sheet includes a pressure sensitive adhesive layer having a surface with unevenness, the pressure sensitive adhesive sheet is stretchable in a planar direction, and a surface peeling force of an object on the pressure sensitive adhesive sheet after stretching is reduced as compared with a surface peeling force of the object on the pressure sensitive adhesive sheet before stretching.

### TECHNICAL FIELD

The present invention relates to a method for peeling an object from a pressure sensitive adhesive sheet.

### BACKGROUND ART

A pressure sensitive adhesive sheet for temporarily holding an object is known. Such a pressure sensitive adhesive sheet can be used for transferring an object to a desired position.

The pressure sensitive adhesive sheet has various shapes depending on its use. For example, Patent Document 1 discloses a technique that enables a pressure sensitive adhesive sheet having functionality to firmly adhere to an adherend and also enables temporary bonding of the pressure sensitive adhesive sheet.

### CITATION LIST

### Patent Literature

Patent Document 1: JP 2004-115766 A

### SUMMARY OF INVENTION

### Technical Problem

When an object is transferred from a pressure sensitive adhesive sheet, an external stimulus may be applied to a substrate for picking up the object to promote peeling. The external stimulus is, for example, pressing by a needle or application of energy by ultraviolet rays or the like, and there is a problem in that damage to the object or the pressure sensitive adhesive sheet is accumulated when the treatment is performed.

An object of the present invention is to provide a pressure sensitive adhesive sheet from which an object is more easily peeled.

### Solution to Problem

As a result of intensive studies, the present inventors have found that in a pressure sensitive adhesive sheet including a pressure sensitive adhesive layer having a surface with unevenness and capable of being stretched in a planar direction, the pressure sensitive adhesive sheet from which an object is more easily peeled can be provided by reducing a surface peeling force of the object on the pressure sensitive adhesive sheet after stretching as compared with the surface peeling force of the object on the pressure sensitive adhesive sheet before the stretching, thereby solving the above problem. Then, through additional various studies, the present invention has been completed.

That is, the present invention relates to [1] to [11] described below.
[1] A method for peeling an object from a pressure sensitive adhesive sheet, the method including:
stretching a pressure sensitive adhesive sheet in a planar direction, the pressure sensitive adhesive sheet including a pressure sensitive adhesive layer having a surface with unevenness, and holding an object on the pressure sensitive adhesive layer; and
peeling the object from the pressure sensitive adhesive layer of the pressure sensitive adhesive sheet stretched in the planar direction.
[2] The peeling method according to [1], in which the peeled object is transferred to a transfer destination different from the pressure sensitive adhesive sheet.
[3] The peeling method according to [2], characterized in that the peeling is performed by bringing the object held by the pressure sensitive adhesive sheet stretched in the planar direction into contact with the transfer destination, and separating the transfer destination from the pressure sensitive adhesive sheet without applying an external stimulus to the pressure sensitive adhesive sheet.
[4] The peeling method according to any one of [1] to [3], in which the pressure sensitive adhesive sheet further includes a base material that supports the pressure sensitive adhesive layer, and
the base material has a tensile elastic modulus of 2500 MPa or less.
[5] The pressure sensitive adhesive sheet according to [4], in which the base material has an elongation at break of 105% or more.
[6] The peeling method according to [4], in which the base material is a polyolefin-based film or a vinyl chloride copolymer film.
[7] The peeling method according to any one of [1] to [6], in which in the stretching, the pressure sensitive adhesive sheet is stretched by 1% or more in the planar direction.
[8] The peeling method according to any one of [1] to [7], in which the pressure sensitive adhesive layer has a plurality of protrusions separated from each other with a boundary defined by a recess, and a pitch of the plurality of protrusions in the pressure sensitive adhesive sheet before the stretching is 1 μm or more and 100 μm or less.
[9] The pressure sensitive adhesive sheet according to [8], in which a pitch of protrusions after the stretching in the pressure sensitive adhesive sheet is 1.05 times or more the pitch of the protrusions before the stretching.
[10] The peeling method according to any one of [1] to [9], in which in the stretching, the pressure sensitive adhesive sheet is stretched by displacing an inner side of a peripheral portion of the pressure sensitive adhesive sheet in a thickness direction of the pressure sensitive adhesive sheet while fixing the peripheral portion of the pressure sensitive adhesive sheet.
[11] The peeling method according to any one of [1] to [10], in which the pressure sensitive adhesive layer is formed of a pressure sensitive adhesive composition containing an energy ray-curable compound.
[12] The peeling method according to any one of [1] to [11], in which the pressure sensitive adhesive layer has a shear storage elastic modulus of 0.001 MPa or more and 100 MPa or less.

### Advantageous Effects of Invention

There is provided a pressure sensitive adhesive sheet from which an object is more easily peeled.

Other features and advantages of the present invention will become apparent from the following description with reference to the accompanying drawings. Note that in the drawings, the same or similar components are denoted by the same reference numerals.

### BRIEF DESCRIPTION OF DRAWINGS

The accompanying drawings, which are incorporated in and constitute a part of the specification, illustrate embodiments of the present invention and serve to explain the principles of the present invention together with the description.

FIG. 1 is a schematic diagram of a pressure sensitive adhesive sheet according to one embodiment.

FIG. 2A is a side view illustrating an example of unevenness of the pressure sensitive adhesive sheet.

FIG. 2B is a side view illustrating an example of unevenness of the pressure sensitive adhesive sheet.

FIG. 3A is a top view illustrating an example of unevenness of the pressure sensitive adhesive sheet.

FIG. 3B is a top view illustrating an example of unevenness of the pressure sensitive adhesive sheet.

FIG. 3C is a top view illustrating an example of unevenness of the pressure sensitive adhesive sheet.

FIG. 4A is a cross-sectional view illustrating an example of unevenness of the pressure sensitive adhesive sheet.

FIG. 4B is a cross-sectional view illustrating an example of unevenness of the pressure sensitive adhesive sheet.

FIG. 4C is a cross-sectional view illustrating an example of unevenness of the pressure sensitive adhesive sheet.

FIG. 5 is a schematic diagram illustrating a pressure sensitive adhesive layer and a release layer.

FIG. 6 is a flowchart of a method for producing an electronic component or a semiconductor device according to one embodiment.

FIG. 7A is a schematic diagram for explaining separation and capture of elements.

FIG. 7B is a schematic diagram for explaining separation and capture of elements.

FIG. 8A is a schematic diagram illustrating stretching of a pressure sensitive adhesive sheet.

FIG. 8B is a schematic diagram illustrating the stretching of the pressure sensitive adhesive sheet.

### DESCRIPTION OF EMBODIMENTS

Hereinafter, embodiments will be described in detail with reference to the drawings. Note that the following embodiments do not limit the invention according to the appended claims, and all combinations of features described in the embodiments are not necessarily essential to the invention. Two or more features among a plurality of features described in the embodiments may be arbitrarily combined. The same or similar components are denoted by the same reference numerals, and redundant description is omitted.

### Definitions

In the present specification, a mass average molecular weight (Mw) and a number average molecular weight (Mn) are values measured by a size exclusion chromatography method and calibrated with a polystyrene standard, and specifically, are values measured based on JIS K7252-1:2016. In addition, in the present specification, “(meth)acrylic acid” is a term referring to both “acrylic acid” and “methacrylic acid”, and the same shall apply to other similar terms.

In the present specification, an “electronic component” encompasses all components used in electronic engineering, electrical engineering, and the like, and all components constituting electronic devices. The “electronic component” may be formed of any one of a semiconductor, a conductor, and/or an insulator, or a combination thereof. Examples of the “electronic component” include active components (mainly formed of semiconductors, such as a transistor, an IC, an LSI, a super LSI, a diode, a light-emitting diode, a thyristor, a three terminal regulator, and an imaging element), passive elements (such as a resistor, a capacitor, a speaker, a coil, a voltage inverter, a transformer, a relay, a piezoelectric element, a quartz oscillator, a ceramic oscillator, and a varistor), and structural components (such as a wiring component, a printed circuit board, a connector, and a switch). In the present specification, a “semiconductor device” refers to any device that can function by utilizing semiconductor characteristics and is used for a processor, a memory, a sensor, or the like. Examples of the “semiconductor device” include a micro light-emitting diode, a mini light-emitting diode, a power device, micro electro mechanical systems (MEMS), and a controller chip.

In the present specification, in a case where one or more lower limit values and one or more upper limit values of a numerical range (for example, a range of a content or the like) are described, it can be understood that a combination of any lower limit value and any upper limit value among them is described. For example, description of 1 or more, 2 or more, and 3 or more, and 9 or less, 8 or less, and 7 or less clearly means that the numerical range may be any of 1 or more and 9 or less, 1 or more and 8 or less, 1 or more and 7 or less, 2 or more and 9 or less, 2 or more and 8 or less, 2 or more and 7 or less, 3 or more and 9 or less, 3 or more and 8 or less, and 3 or more and 7 or less.

The pressure sensitive adhesive sheet according to the present embodiment includes a pressure sensitive adhesive layer having a surface with unevenness, and is stretchable in a planar direction. A surface peeling force of an object on the pressure sensitive adhesive sheet after stretching in the planar direction is lower than a surface peeling force of the object on the pressure sensitive adhesive sheet before stretching. Here, the surface peeling force refers to an adhesive force at the time of picking up an object from a pressure sensitive adhesive sheet, which is measured, for example, in Examples described below. When the surface peeling force is reduced and the object is easily peeled, the object can be picked up without an external stimulus such as a stimulus by a needle or energy application or with a reduced amount of the external stimulus, which can reduce damage to each constituent member. Hereinafter, the pressure sensitive adhesive layer having a surface with unevenness included in the pressure sensitive adhesive sheet according to the present embodiment will be described.

### Pressure Sensitive Adhesive Sheet

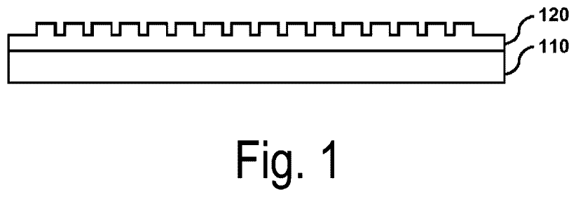

The pressure sensitive adhesive sheet according to the present embodiment may include a pressure sensitive adhesive layer for capturing an object separated from a holding substrate, and a base material for supporting the pressure sensitive adhesive layer. FIG. 1 illustrates a schematic diagram of the pressure sensitive adhesive sheet according to the present embodiment. In one embodiment, as illustrated in FIG. 1, the pressure sensitive adhesive sheet may include a pressure sensitive adhesive layer 110 and a base material 120. However, it is not essential that the pressure sensitive adhesive sheet has the base material 120. For example, the pressure sensitive adhesive sheet may be composed of only the pressure sensitive adhesive layer 110. In this case, the pressure sensitive adhesive layer 110 having a high supporting property can be used. Each component of the pressure sensitive adhesive sheet will be described below.

### Pressure Sensitive Adhesive Layer

The pressure sensitive adhesive layer 110 according to the present embodiment is a layer having adhesiveness and can include a resin. As described above, the surface of the pressure sensitive adhesive layer 110 has unevenness. Note that the pressure sensitive adhesive sheet may have two or more pressure sensitive adhesive layers 110. For example, the pressure sensitive adhesive sheet may have a laminate of one type or two or more types of pressure sensitive adhesive layers 110.

### Shear Storage Elastic Modulus

The shear storage elastic modulus of the pressure sensitive adhesive layer 110 is preferably 0.001 MPa or more, more preferably 0.01 MPa or more, even more preferably 0.05 MPa or more, and still more preferably 0.1 MPa or more, from the viewpoint of shape stability of the uneven shape of the surface of the pressure sensitive adhesive layer. On the other hand, it is preferable that the shear storage elastic modulus of the pressure sensitive adhesive layer 110 is low in terms of being able to suppress positional deviation when capturing an object. From such a viewpoint, the shear storage elastic modulus of the pressure sensitive adhesive layer 110 is preferably 100 MPa or less, more preferably 10 MPa or less, even more preferably 5 MPa or less, still more preferably 2 MPa or less, still even more preferably 1 MPa or less, yet more preferably 0.5 MPa or less, yet even more preferably 0.3 MPa or less, yet still more preferably 0.25 MPa or less, and yet still even more preferably 0.2 MPa or less. In the present specification, the shear storage elastic modulus means a value measured by a method described in Examples below.

### Surface Peeling Force Before Stretching

The surface peeling force of the pressure sensitive adhesive layer 110 before stretching is preferably 0.01 N/25 mm or more, more preferably 0.1 N/25 mm or more, even more preferably 1.0 N/25 mm or more, still more preferably 2.0 N/25 mm or more, and particularly preferably 3.0 N/25 mm or more from the viewpoint of suppressing positional deviation when capturing an object. The surface peeling force of the pressure sensitive adhesive layer 110 before stretching is preferably 100 N/25 mm or less, more preferably 10 N/25 mm or less, and even more preferably 5 N/25 mm or less, from the viewpoint of peeling the captured object from the pressure sensitive adhesive layer without damaging the captured object. In the present specification, the surface peeling force means a value measured by a method described in the Examples described below.

Surface Peeling Force after Stretching

The surface peeling force of the pressure sensitive adhesive layer 110 after stretching is preferably 0.01 N/25 mm or more, more preferably 0.1 N/25 mm or more, even more preferably 0.5 N/25 mm or more, still more preferably 1.0 N/25 mm or more, and particularly preferably 1.5 N/25 mm or more, from the viewpoint of suppressing the positional deviation before the object is peeled. The surface peeling force of the pressure sensitive adhesive layer 110 after stretching is preferably 10 N/25 mm or less, more preferably 5 N/25 mm or less, and even more preferably 3 N/25 mm 1 or less, from the viewpoint of peeling the captured object from the pressure sensitive adhesive layer without damaging the captured object. In the present specification, the surface peeling force after stretching means a value measured by a method described in the Examples described below.

### Stretching Step of Pressure Sensitive Adhesive Layer

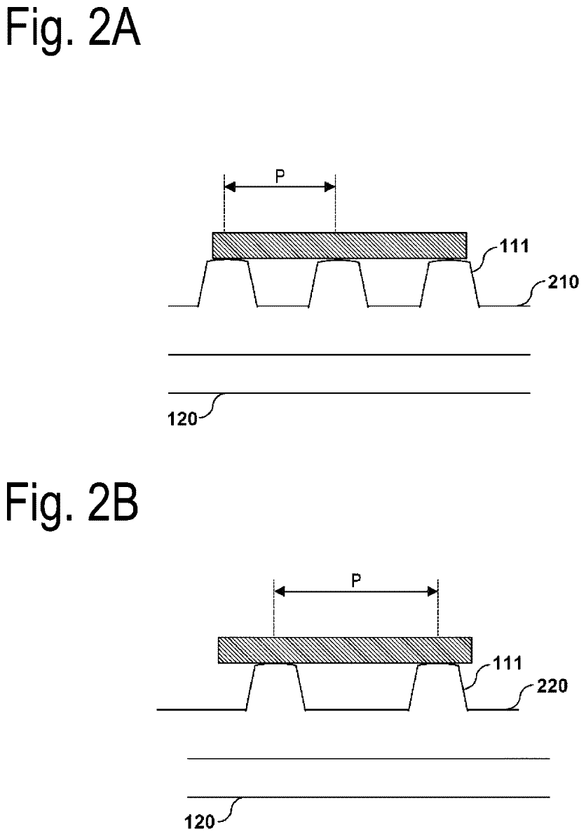

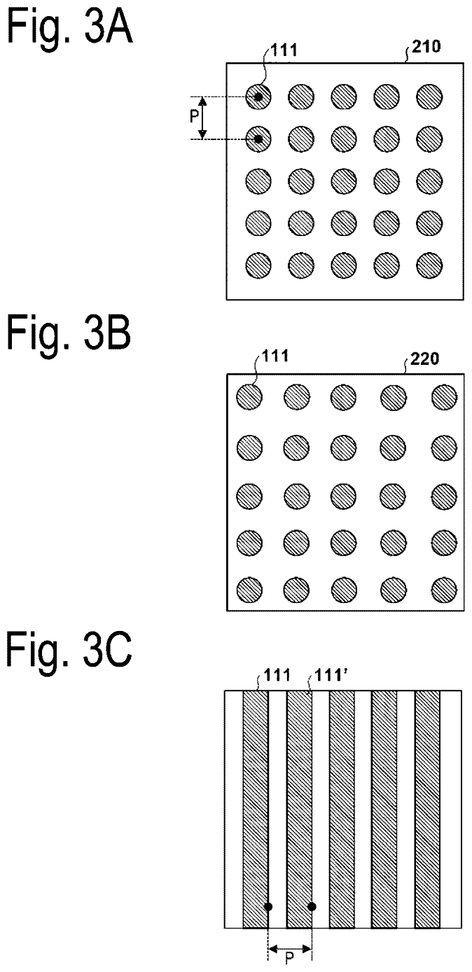

The pressure sensitive adhesive sheet including the pressure sensitive adhesive layer 110 according to the present embodiment can be stretched (extended) in the planar direction as described above. Hereinafter, a step of stretching the pressure sensitive adhesive sheet in the planar direction according to the present embodiment will be described with reference to examples of shapes of the pressure sensitive adhesive layer illustrated in FIGS. 2A and 2B, and FIGS. 3A, 3B, and 3C. Note that the stretching treatment in the planar direction of the pressure sensitive adhesive sheet may be referred to as “extension (of the pressure sensitive adhesive sheet)” below.

The surface of the pressure sensitive adhesive layer 110 according to the present embodiment has unevenness. In one embodiment, the pressure sensitive adhesive layer 110 has a plurality of protrusions on its surface, which are separated from each other with a boundary defined by a recess. Each of the plurality of protrusions may be separated by a recess that is continuous over the entire pressure sensitive adhesive layer 110.

FIGS. 2A and 2B are side views each illustrating a shape of the pressure sensitive adhesive layer 110, and FIGS. 3A, 3B, and 3C are top views each illustrating a shape of the pressure sensitive adhesive layer 110. FIGS. 2A and 3A illustrate an example of the pressure sensitive adhesive layer 110 before stretching, and FIGS. 2B and 3B illustrate an example of the pressure sensitive adhesive layer 110 after stretching. In addition, while an element 140 which is an object supplemented by the protrusions of the pressure sensitive adhesive layer 110 is depicted in FIGS. 2A and 2B, the element 140 captured by the protrusions is omitted in FIGS. 3A, 3B, and 3C. Hereinafter, various descriptions will be made on the assumption that the object captured by the pressure sensitive adhesive sheet is the element 140, but the type of the object is not particularly limited thereto. As will be described in more detail below, the object may be a singulated product such as a wafer, a panel, or a substrate.

Hereinafter, when simply referred to as a “protrusion” or a “recess”, a protrusion or a recess of the pressure sensitive adhesive layer 110 is referred to. As illustrated in FIGS. 2A and 3A, protrusions 111 are regularly arranged on the surface of the pressure sensitive adhesive layer 110. The regular arrangement of the protrusions 111 means that the protrusions 111 are arranged on a straight line at a constant pitch P, and here, the protrusions 111 are arranged in a lattice shape.

In the present embodiment, the pressure sensitive adhesive sheet is stretched, and a pressure sensitive adhesive layer 210 illustrated in FIGS. 2A and 3A is deformed into a pressure sensitive adhesive layer 220 illustrated in FIGS. 2B and 3B. When the pressure sensitive adhesive layer 210 and the pressure sensitive adhesive layer 220 are compared with each other, in the pressure sensitive adhesive layer 220, the pitch P of the protrusions 111 is increased by stretching, and the number of protrusions 111 that capture one base material 230 is reduced. Accordingly, in the pressure sensitive adhesive layer 220, the force for holding the base material 230 by the protrusions 111 is reduced, leading to reduction in the surface peeling force, as compared with the pressure sensitive adhesive layer 210. Although the pitch P is constant over the entire region of the pressure sensitive adhesive sheet in the present embodiment, the pitch P may be non-uniform, for example, the pitch P may become smaller in a predetermined region of the pressure sensitive adhesive sheet.

Note that FIG. 3C is a top view illustrating another shape of the pressure sensitive adhesive layer 110. As illustrated in FIG. 3C, stripe-shaped protrusions 111 may be provided on the pressure sensitive adhesive layer 110. In FIG. 3C, linear protrusions 111 having a constant width are arranged at constant intervals. The width or interval of the linear protrusions 111 may vary regularly, or the linear protrusions 111 may be arranged irregularly.

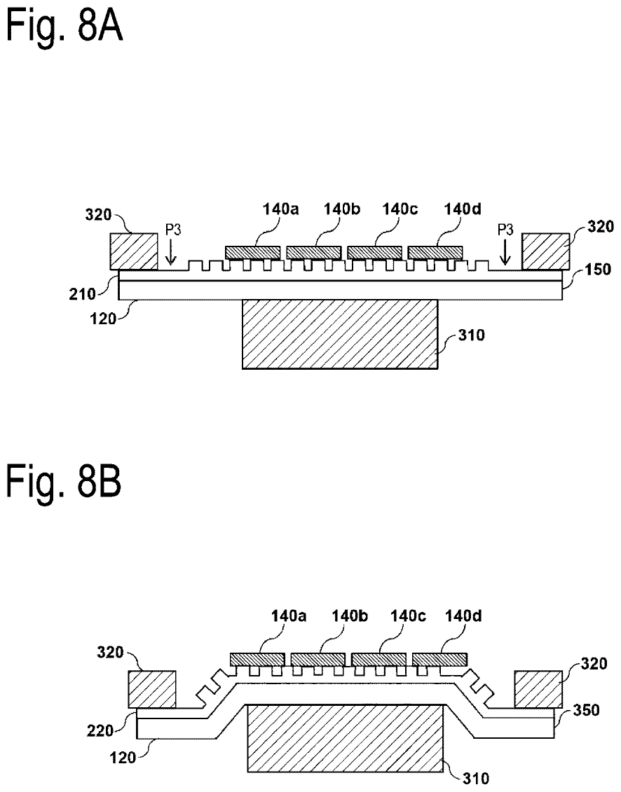

Hereinafter, an example of the stretching treatment will be described with reference to FIGS. 8A and 8B. In the present embodiment, as illustrated in FIGS. 8A and 8B, a pedestal 310 is disposed to be in contact with the base material 120 of a pressure sensitive adhesive sheet 150, and the pressure sensitive adhesive layer 210 and the base material 120 in FIG. 8A are pressed against the pedestal 310 by pulling down an inner side of a peripheral portion of the pressure sensitive adhesive sheet 150 to the pedestal 310 while fixing the peripheral portion. As a result, as illustrated in FIG. 8B, the pressed site of the pressure sensitive adhesive layer 210 is displaced in the thickness direction and is deformed into the pressure sensitive adhesive layer 220 in which the pitch P is enlarged. As described above, the “stretching” treatment according to the present embodiment is a treatment in which the inner side of the fixed peripheral portion of the pressure sensitive adhesive sheet is displaced in the thickness direction. The pedestal 310 has a rectangular parallelepiped shape, for example, and is disposed outside the pressure sensitive adhesive sheet. The pedestal 310 may be arranged in a lattice shape, for example, and may be movably mounted at a location where an object is picked up.

The pressure sensitive adhesive sheet may be extensible by stretching, for example, by 1% or more in the planar direction. Although the pressure sensitive adhesive sheet according to the present embodiment is described as being extended in all directions, the pressure sensitive adhesive sheet may be extended in one direction, two directions, or a plurality of other directions. The extension of the pressure sensitive adhesive sheet in the planar direction is evaluated by, for example, an expansion rate of the pitch P by stretching. That is, the expansion rate of the pitch P by stretching may be 1% or more, 5% or more, or 10% or more, and can be arbitrarily set. Here, the pitch P after stretching relative to the value before stretching is preferably 1.05 times or more, more preferably 1.1 times or more, even more preferably 1.2 times or more, and still more preferably 1.5 times or more, from the viewpoint of reducing the surface peeling force. In addition, the pitch P after stretching relative to the value before stretching is preferably 3 times or less, more preferably 2.8 times or less, even more preferably 2.5 times or less, and still more preferably 2.0 times or less, from the viewpoint of ensuring the minimum surface peeling force.

As described above, this stretching treatment is performed by pulling down the inner side of the peripheral portion of the pressure sensitive adhesive sheet to the pedestal 310 while fixing the peripheral portion. The displacement amount of the pressure sensitive adhesive sheet in the thickness direction by this stretching can be any amount that can increase the pitch P to a desired extent, and is preferably 5 mm, more preferably 10 mm, even more preferably 15 mm, still more preferably 20 mm, still even more preferably 50 mm, and yet more preferably 80 mm, for example. In addition, here, to fix the peripheral portion of the pressure sensitive adhesive sheet, a fixing portion of a perfect circle system is used, and the plane of the pedestal 310 pressed against the pressure sensitive adhesive sheet is also a perfect circle system, but this is an example, and the shapes thereof are not particularly limited, and one or both of these shapes may be a square shape or the like. For example, when a circular frame as the fixing portion is used to press down a frame in a state where the pressure sensitive adhesive sheet fixed to the frame is placed on the pedestal 310, stretching can be performed to extend the pressure sensitive adhesive sheet in all directions.

The pitch P of the protrusions 111 before stretching is preferably 1 μm or more, more preferably 5 μm or more, even more preferably 10 μm or more, and still more preferably 15 μm or more, from the viewpoint of adjusting the surface peeling force. On the other hand, the pitch P is preferably 100 μm or less, more preferably 75 μm or less, even more preferably 50 μm or less, still more preferably 35 μm or less, and still even more preferably 25 μm or less, from the viewpoint of increasing the contact area between the pressure sensitive adhesive layer 110 and an element to enhance the surface peeling force. Here, the pitch P of the protrusions 111 means a distance between a center point of one protrusion 111 arbitrarily selected and a center point of another protrusion 111 closest to the protrusion 111. For example, in a case of FIG. 2A, the pitch P of the protrusions 111 represents the distance between a center point of a protrusion 111 on a straight line on which the protrusions 111 are arranged at regular intervals and a center point of another protrusion 111′ closest to the protrusion 111. When the protrusions 111 are arranged on a plurality of straight lines, the pitch P represents the distance between center points of protrusions on a straight line on which the protrusions 111 are arranged at the shortest pitch. In the present specification, the interval between the protrusions 111 means an interval between centers of the protrusions.

A specific shape of each of the protrusions 111 is not particularly limited. For example, the protrusions 111 may each have a pillar (column) shape. As a specific example, the protrusions 111 may each have a circular column shape or a prismatic column shape. In addition, the protrusions 111 may each extend in a line shape as described above, or may extend in a curved shape such as a wave shape. Furthermore, the protrusions 111 may be each provided with a taper.

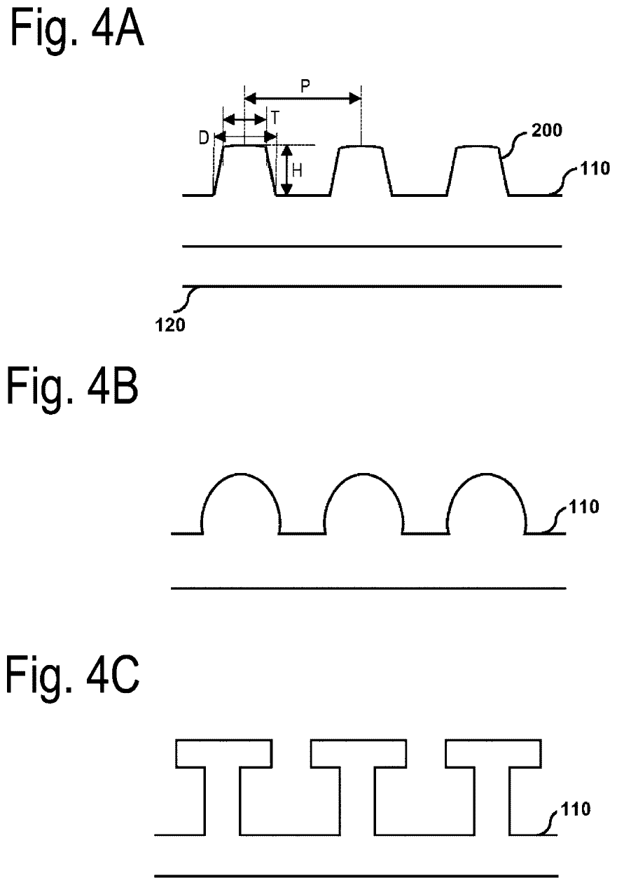

FIG. 4A illustrates a cross-sectional view of the pressure sensitive adhesive layer 110 according to one embodiment through the protrusions 111 and perpendicular to the surface of the pressure sensitive adhesive layer 110. The protrusions 111 illustrated in FIG. 4A are each provided with a taper, that is, the protrusions 111 are tapered. In addition, as illustrated in FIG. 4B, the tip of each of the protrusions 111 may be curved. With such a configuration, an impact when an element separated from the holding substrate and the pressure sensitive adhesive layer 110 come into contact with each other is further alleviated, and thus it becomes easy for the pressure sensitive adhesive layer 110 to capture the element not to be displaced. On the other hand, the tip of each of the protrusions may be flat.

As illustrated in FIG. 4A, the surface of the pressure sensitive adhesive layer 110 may have a flat recess and the protrusions 111 protruding from the recess. As described above, boundaries of the plurality of protrusions 111 included in the pressure sensitive adhesive layer 110 and separated from each other may be defined by the recess.

As another example, the protrusions may be each hemispherical or a portion of a sphere as illustrated in FIG. 4B. In addition, as illustrated in FIG. 4C, the protrusions 111 may each have a T-shape. As still another example, the protrusions 111 may each have a shape in which a plurality of grains are gathered, a mushroom shape, a lotus leaf surface shape, or a needle shape. As still another example, the surface of the pressure sensitive adhesive layer 110 may be rough or fibrous, and it can be said that such a surface also has unevenness.

A width or diameter of each of the protrusions 111 is preferably 1 μm or more, more preferably 2 μm or more, even more preferably 5 μm or more, and still more preferably 10 μm or more. On the other hand, the width or diameter is preferably 100 μm or less, more preferably 50 μm or less, even more preferably 30 μm or less, and still more preferably 20 μm or less. This can change the holding property for the element. Here, the width and diameter of each of the protrusions 111 mean the minimum distance and the maximum distance (indicated by D in FIG. 4A) between two parallel lines coming into contact with both sides of the protrusion 111 on the surface of the recess, respectively.

An area of each of the protrusions 111 is preferably 10 μm² or more, more preferably 20 μm² or more, and even more preferably 30 μm² or more. On the other hand, the area is preferably 2000 μm² or less, more preferably 1000 μm² or less, and even more preferably 500 μm² or less. This can change the holding property for the element. Here, the area of each of the protrusions 111 means an area of a portion protruding from the surface of the recess (in a case of FIG. 4A, an area of a circle having a diameter D).

A height of each of the protrusions 111 is preferably 1 μm or more, more preferably 3 μm or more, and even more preferably 5 μm or more. On the other hand, the height of each of the protrusions 111 is preferably 20 μm or less, more preferably 15 μm or less, and even more preferably 10 μm or less. This can change the holding property for the element. Here, the height of each of the protrusions 111 is represented by H in FIG. 4A.

A total area of the protrusions 111 relative to the area of the pressure sensitive adhesive layer 110 is preferably 1% or more, more preferably 5% or more, even more preferably 10% or more, still more preferably 18% or more, and still even more preferably 40% or more. On the other hand, the total area of the protrusions relative to the area of the pressure sensitive adhesive layer 110 is preferably 95% or less, more preferably 75% or less, and even more preferably 60% or less. This can change the holding property for the element.

The unevenness of the pressure sensitive adhesive layer 110 may be designed depending on the shape of the element to be held by the pressure sensitive adhesive sheet. For example, a ratio of an adhesion area between the pressure sensitive adhesive layer 110 and one element to an area of the one element is preferably 1% or more, more preferably 2% or more, even more preferably 3% or more, still more preferably 4% or more, still even more preferably 5% or more, yet more preferably 7% or more, and yet even more preferably 10% or more, with respect to 100% of the area of the one element. On the other hand, the ratio of the adhesion area between the pressure sensitive adhesive layer 110 and one element to the area of the one element is preferably 95% or less, more preferably 70% or less, even more preferably 50% or less, and still more preferably 30% or less. In the case of FIG. 4A, the adhesion area corresponds to the area of a circle with a radius T. Note that in a case where the capturing position of the element on the pressure sensitive adhesive sheet is shifted, the adhesion area may be changed. In this case, the ratio of the adhesion area may fall within the above-described range regardless of the capture position of the element.

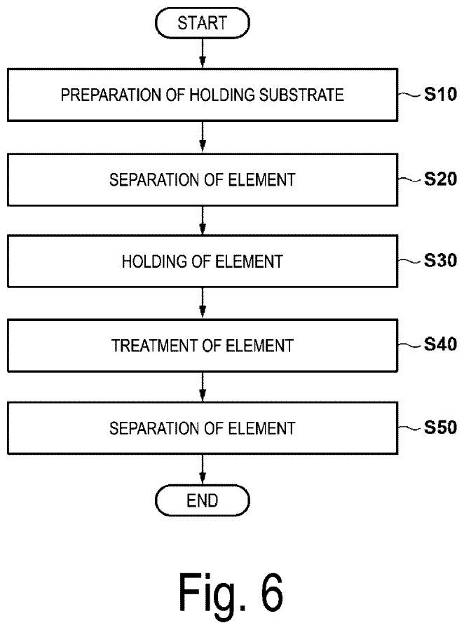

In the present embodiment, the element 140 is peeled from a pressure sensitive adhesive layer 120 extended in the planar direction. Here, for example, the element 140 held by the pressure sensitive adhesive sheet extended in the planar direction is brought into contact with a transfer destination different from the pressure sensitive adhesive sheet and then the transfer destination is separated, whereby the element 140 can be peeled to the transfer destination. As described above, the surface of the pressure sensitive adhesive layer 120 has unevenness, and the surface peeling force is reduced by stretching. Thus, in a step of peeling the element 140 according to the present embodiment, for example, the element 140 is peeled by bringing the element 140 into contact with a transfer destination and separating the transfer destination from the pressure sensitive adhesive sheet without applying an external stimulus to the pressure sensitive adhesive sheet. Here, the external stimulus is a stimulus from the outside, such as energy application or pressing by a needle, which is used to reduce the adhesion between the holding substrate and the element in FIG. 6 described below. As described above, when the object is picked up without an external stimulus (or with a reduced external stimulus), it is possible to peel the object while reducing damage to each constituent member.

### Composition of Pressure Sensitive Adhesive Layer (Pressure Sensitive Adhesive Composition)

A pressure sensitive adhesive composition forming the pressure sensitive adhesive layer 110 includes a resin. Examples of the resin included in the pressure sensitive adhesive composition include a rubber-based resin such as a polyisobutylene-based resin, a polybutadiene-based resin, and a styrene-butadiene-based resin, an acrylic resin, a urethane-based resin, a polyester-based resin, an olefin-based resin, a silicone-based resin, and a polyvinyl ether-based resin. In addition, the pressure sensitive adhesive layer may have heat resistance, and examples of a material of such a pressure sensitive adhesive layer having heat resistance include a polyimide-based resin and a silicone-based resin. The pressure sensitive adhesive composition forming the pressure sensitive adhesive layer 110 may contain a copolymer having two or more types of constituent units. A form of such a copolymer is not particularly limited, and the copolymer may be any of a block copolymer, a random copolymer, an alternating copolymer, or a graft copolymer. The resin contained in the pressure sensitive adhesive composition forming the pressure sensitive adhesive layer 110 may be composed of one type of resin or may be composed of two or more types of resins.

The resin contained in the pressure sensitive adhesive composition forming the pressure sensitive adhesive layer 110 may be an adhesive resin having adhesiveness by itself. The resin may be a polymer having a mass average molecular weight (Mw) of 10000 or more. From the viewpoint of improving the adhesive force, the mass average molecular weight (Mw) of the resin is preferably 10000 or more, more preferably 70000 or more, and even more preferably 140000 or more. In addition, from the viewpoint of suppressing the shear storage elastic modulus to a predetermined value or less, the Mw is preferably 2000000 or less, more preferably 1200000 or less, and even more preferably 900000 or less. The number average molecular weight (Mn) of the resin is preferably 10000 or more, more preferably 50000 or more, and even more preferably 100000 or more, from the viewpoint of improving the adhesive force. The Mn is preferably 2000000 or less, more preferably 1000000 or less, and even more preferably 700000 or less, from the viewpoint of suppressing the shear storage elastic modulus to a predetermined value or less. As will be described below, in a case where the pressure sensitive adhesive layer 110 contains a resin derived from an energy ray-curable resin, the mass average molecular weight (Mw) and the number average molecular weight (Mn) refer to the mass average molecular weight (Mw) and the number average molecular weight (Mn) before a cross-linking reaction by energy application.

The glass transition temperature (Tg) of the resin is preferably −75° C. or higher, and more preferably −70° C. or higher, and preferably −10° C. or lower, and more preferably −20° C. or lower. When the Tg is within the above range, the shear storage elastic modulus of the resulting pressure sensitive adhesive layer can be easily within the range described below.

The amount of the resin relative to the total amount of the components constituting the pressure sensitive adhesive composition forming the pressure sensitive adhesive layer 110 can be appropriately set depending on the required adhesive force and shear storage elastic modulus of the pressure sensitive adhesive layer 110, and is preferably 30 mass % or more, more preferably 40 mass % or more, even more preferably 50 mass % or more, still more preferably 55 mass % or more, still even more preferably 60 mass % or more, and preferably 99.99 mass % or less, more preferably 99.95 mass % or less, even more preferably 99.90 mass % or less, still more preferably 99.80 mass % or less, and still even more preferably 99.50 mass % or less.

### Thermoplastic Resin

In one embodiment, the resin included in the pressure sensitive adhesive composition forming the pressure sensitive adhesive layer 110 may include a thermoplastic resin. That is, the pressure sensitive adhesive layer 110 can be formed of a thermoplastic resin. In a case of using a thermoplastic resin, it is easy to form unevenness on the pressure sensitive adhesive layer 110 by heating and softening the resin, and it is easy to maintain the formed uneven shape by cooling the resin. Examples of the thermoplastic resin include a rubber-based resin, an acrylic resin, a urethane-based resin, and an olefin-based resin. Examples of the thermoplastic resin include a polybutadiene-based thermoplastic elastomer in which butadiene is used as a monomer, a styrene-based thermoplastic elastomer in which styrene is used as a monomer, and an acrylic thermoplastic elastomer in which a (meth)acrylic acid ester is used as a monomer.

### Energy Ray-Curing Resin (A)

The resin contained in the pressure sensitive adhesive composition forming the pressure sensitive adhesive layer 110 according to the present embodiment may contain an energy ray-curable resin (A). The “energy ray-curable” means a property of being cured by irradiation with an energy ray, and the energy ray-curable resin (A) refers to a resin that is cured by irradiation with an energy ray. Moreover, the “energy ray” means an electromagnetic wave or a charged particle beam having an energy quantum, and examples thereof include an ultraviolet ray, a radioactive ray, or an electron beam. The ultraviolet ray can be irradiated by using, for example, an electrodeless lamp, a high-pressure mercury lamp, a metal halide lamp, or a UV-LED as an ultraviolet ray source. The electron beam can be generated by an electron beam accelerator or the like and irradiated. The “energy ray-polymerizable” refers to a property of being polymerized by irradiation with an energy ray.

In a case of using such an energy ray-curable resin (A), when energy is applied (for example, by irradiation with an energy ray) after forming unevenness on the resin, it becomes easy to maintain the formed uneven shape.

From the viewpoint of improving the adhesive force, the mass average molecular weight (Mw) of the energy ray-curable resin (A) is preferably 10000 or more, more preferably 50000 or more, even more preferably 100000 or more, and still more preferably 150000 or more. In addition, from the viewpoint of suppressing the shear storage elastic modulus to a predetermined value or less, the Mw is preferably 2000000 or less, more preferably 1000000 or less, and even more preferably 200000 or less.

As the energy ray-curable resin (A), a polymer into which a polymerizable functional group is introduced can be used. The polymerizable functional group is a functional group that is cross-linked by application of energy (for example, irradiation with an energy ray). Examples of the polymerizable functional group include an alkenyl group such as a vinyl group and an allyl group, a (meth)acryloyl group, an oxetanyl group, and an epoxy group.

The average number of polymerizable functional groups per molecule in the energy ray-curable resin (A) is preferably 1.5 or more, and more preferably 2 or more, from the viewpoint of easily maintaining the uneven shape of the pressure sensitive adhesive layer. On the other hand, this average value is preferably 20 or less, more preferably 15 or less, and even more preferably 10 or less, from the viewpoint of enhancing the adhesiveness and flexibility of the pressure sensitive adhesive layer.

In one embodiment, as the energy ray-curable resin (A), a diene-based rubber composed of a polymer having a polymerizable functional group at a main chain terminal and/or a side chain can be used. The diene-based rubber refers to a rubbery polymer having a double bond in the polymer main chain. Specific examples of the diene-based rubber include a polymer in which butadiene or isoprene is used as a monomer (that is, a polymer having a butenediyl group or a pentenediyl group as a constituent unit). In one embodiment, examples of the energy ray-curable resin (A) include a polybutadiene resin (PB resin), a styrene-butadiene-styrene block copolymer (SBS resin), and a styrene-isoprene-styrene block copolymer.

The amount of the energy ray-curable resin (A) in the total amount of the resins of the pressure sensitive adhesive composition can be appropriately set depending on the required adhesive force and shear storage elastic modulus of the pressure sensitive adhesive layer 110, and is preferably 0 mass % or more, more preferably 10 mass % or more, even more preferably 20 mass % or more, and still more preferably 50 mass % or more, and preferably 100 mass % or less, and more preferably 97 mass % or less.

### Acrylic Resin (B)

In one embodiment, the thermoplastic resin can be an acrylic resin (B). The mass average molecular weight (Mw) of the acrylic resin (B) is preferably 10000 or more, more preferably 100000 or more, and even more preferably 500000 or more, from the viewpoint of improving the adhesive force. From the viewpoint of suppressing the shear storage elastic modulus to a predetermined value or less, the Mw is preferably 2000000 or less, more preferably 1500000 or less, and even more preferably 1000000 or less.

The glass transition temperature (Tg) of the acrylic resin (B) is preferably −75° C. or higher, and more preferably −70° C. or higher, and preferably 5° C. or lower, and more preferably −20° C. or lower. When the Tg is within the above range, the shear storage elastic modulus of the resulting pressure sensitive adhesive is easily within the range.

In a case where the acrylic resin (B) has two or more constituent units, the glass transition temperature (Tg) of the acrylic resin (B) can be calculated using a Fox equation. For the Tg of the monomer deriving the constituent unit used at this time, a value described in Polymer Data Handbook or Pressure Sensitive Adhesion Handbook can be used.

Examples of the (meth)acrylate constituting the acrylic resin (B) include: alkyl (meth)acrylates in which the alkyl group constituting the alkyl ester has a chain structure having from 1 to 18 carbons, such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, pentyl (meth)acrylate, hexyl (meth)acrylate, heptyl (meth)acrylate, 2-ethylhexyl (meth)acrylate, isooctyl (meth)acrylate, n-octyl (meth)acrylate, n-nonyl (meth)acrylate, isononyl (meth)acrylate, decyl (meth)acrylate, undecyl (meth)acrylate, lauryl (meth)acrylate, tridecyl (meth)acrylate, myristyl (meth)acrylate, pentadecyl (meth)acrylate, palmityl (meth)acrylate, heptadecyl (meth)acrylate, and stearyl (meth)acrylate; cycloalkyl (meth)acrylates, such as isobornyl (meth)acrylate and dicyclopentanyl (meth)acrylate; aralkyl (meth)acrylates, such as benzyl (meth)acrylate; cycloalkenyl (meth)acrylates, such as dicyclopentenyl (meth)acrylate; cycloalkenyloxyalkyl (meth)acrylates, such as dicyclopentenyloxyethyl (meth)acrylate; imide (meth)acrylate; glycidyl group-containing (meth)acrylates, such as glycidyl (meth)acrylate; hydroxyl group-containing (meth)acrylates, such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; and substituted amino group-containing (meth)acrylates, such as N-methylaminoethyl (meth)acrylate. Here, the “substituted amino group” means a group having a structure in which one or two hydrogen atoms of an amino group are substituted with a group other than hydrogen atoms.

The acrylic resin (B) may be a resin formed by copolymerization of one or two or more types of monomers selected from, for example, (meth)acrylic acid, itaconic acid, vinyl acetate, acrylonitrile, styrene, and N-methylolacrylamide in addition to (meth)acrylates.

The acrylic resin (B) may be constituted of only one type or two or more types of monomers. When two or more types of monomers constitute the acrylic resin, their combination and ratio can be freely selected.

The acrylic resin (B) may have a functional group, such as a vinyl group, a (meth)acryloyl group, an amino group, a carboxy group, and an isocyanate group, which can be bonded to another compound, in addition to a hydroxyl group. These functional groups including a hydroxyl group of the acrylic resin (B) may be bonded to another compound via a cross-linking agent (C) described below or may be directly bonded to another compound without the cross-linking agent (C).

The amount of the acrylic resin (B) in the total amount of the resins of the pressure sensitive adhesive composition can be appropriately set depending on the required adhesive force and shear storage elastic modulus of the pressure sensitive adhesive layer 110, and is preferably 0 mass % or more, more preferably 10 mass % or more, even more preferably 20 mass % or more, and still more preferably 50 mass % or more, and preferably 100 mass % or less, more preferably 95 mass % or less, even more preferably 80 mass % or less, and still more preferably 60 mass % or less.

In one embodiment, the pressure sensitive adhesive composition can contain the energy ray-curable resin (A) and the acrylic resin (B). The content relationship of the energy ray-curable resin (A) and the acrylic resin (B) can be appropriately set depending on the required adhesive force and shear storage elastic modulus of the pressure sensitive adhesive layer 110. In one embodiment, the content rate of the acrylic resin (B) in the total content of the energy ray-curable resin (A) and the acrylic resin (B) is preferably 0 mass % or more, more preferably 10 mass % or more, even more preferably 20 mass % or more, and still more preferably 50 mass % or more, and preferably 100 mass % or less, more preferably 95 mass % or less, even more preferably 80 mass % or less, and still more preferably 60 mass % or less.

The pressure sensitive adhesive composition forming the pressure sensitive adhesive layer 110 may contain components other than the resins. For example, the pressure sensitive adhesive composition may contain one or more of a cross-linking agent (C), a photopolymerization initiator (D), an antioxidant (E), and other additives.

### Cross-Linking Agent (C)

The pressure sensitive adhesive composition may contain the cross-linking agent (C) for bonding and cross-linking a functional group of a resin with another compound. Examples of the cross-linking agent (C) include isocyanate-based cross-linking agents (i.e., cross-linking agents having an isocyanate group), such as tolylene diisocyanate, hexamethylene diisocyanate, and xylylene diisocyanate, and adducts of these diisocyanates; epoxy-based cross-linking agents (i.e., cross-linking agents having a glycidyl group), such as ethylene glycol glycidyl ether; aziridine-based cross-linking agents (i.e., cross-linking agents having an aziridinyl group), such as hexa [1-(2-methyl)-aziridinyl]triphosphatriazine; metal chelate-based cross-linking agents (i.e., cross-linking agents having a metal chelate structure), such as aluminum chelates; and isocyanurate-based cross-linking agents (i.e., cross-linking agents having an isocyanuric acid backbone).

The pressure sensitive adhesive composition may contain one type of cross-linking agent or two or more types of cross-linking agents. The content of the cross-linking agent (C) in the pressure sensitive adhesive composition is preferably 0.01 mass % or more, more preferably 0.1 mass % or more, and even more preferably 1 mass % or more, and preferably 5 mass % or less, more preferably 4 mass % or less, and even more preferably 2 mass % or less, from the viewpoint of appropriately performing a cross-linking reaction.

### Photopolymerization Initiator (D)

The pressure sensitive adhesive composition may contain the photopolymerization initiator (D) that initiates a cross-linking reaction in response to application of energy (for example, irradiation with an energy ray). In a case where the pressure sensitive adhesive composition contains the energy ray-curable resin (A), when the pressure sensitive adhesive layer 110 further contains the photopolymerization initiator (D), the cross-linking reaction proceeds even by application of relatively low energy.

Examples of the photopolymerization initiator (D) include 1-hydroxycyclohexyl phenyl ketone, benzoin, benzoin methyl ether, benzoin ethyl ether, benzoin propyl ether, benzyl phenyl sulfide, tetramethylthiuram monosulfide, azobisisobutyronitrile, dibenzyl, diacetyl, 8-chloroanthraquinone, and bis(2,4,6-trimethylbenzoyl)phenylphosphine oxide.

The pressure sensitive adhesive composition may contain one type of polymerization initiator or may contain two or more types of polymerization initiators. The content of the photopolymerization initiator (D) in the pressure sensitive adhesive composition is preferably 0.01 mass % or more, more preferably 0.1 mass % or more, and even more preferably 1 mass % or more, and preferably 10 mass % or less, more preferably 5 mass % or less, and even more preferably 2 mass % or less.

### Antioxidant (E)

The pressure sensitive adhesive composition may contain the antioxidant (E). Examples of the antioxidant (E) include phenol-based antioxidants such as a hindered phenol-based compound, aromatic amine-based antioxidants, sulfur-based antioxidants, and phosphorus-based antioxidants such as a phosphoric acid ester-based compound.

Furthermore, the pressure sensitive adhesive composition forming the pressure sensitive adhesive layer 110 may contain one or more of an ultraviolet absorber, a light stabilizer, a resin stabilizer, a filler, a pigment, an extender, a softener, and the like.

### Base Material

The base material 120 included in the pressure sensitive adhesive sheet according to the present embodiment functions as a backing that supports the pressure sensitive adhesive layer 110. The type of the base material 120 is not particularly limited, and may be a rigid base material or a flexible base material. The base material 120 may be a flexible base material from the viewpoint of improving a cushioning property at the time of capturing an element, facilitating attachment to another member, improving a peeling property, facilitating lamination, or being made into a roll form. As the base material 120, for example, a resin film can be used.

The resin film is a film in which a resin-based material is used as a main material, and may be made of a resin material or may contain an additive in addition to the resin material. The resin film may have laser light transmissivity.

Specific examples of the resin film include polyolefin-based films such as polyethylene films such as low-density polyethylene films, linear low-density polyethylene films, and high-density polyethylene films, polypropylene films, polybutene films, polybutadiene films, polymethylpentene films, ethylene-norbornene copolymer films, and norbornene resin films; ethylene-based copolymer films such as ethylene-vinyl acetate copolymer films, ethylene-(meth)acrylic acid copolymer films, and ethylene-(meth)acrylic ester copolymer films; polyvinyl chloride-based films such as polyvinyl chloride films and vinyl chloride copolymer films; polyester-based films such as polyethylene terephthalate films and polybutylene terephthalate films; polyurethane films; polyimide films; polystyrene films; polycarbonate films; and fluororesin films. In addition, a film containing a mixture of two or more types of materials, a cross-linked film in which resins forming these films are cross-linked, and a modified film such as an ionomer film may be used. The base material 120 may be a laminated film in which two or more types of resin films are laminated.

From the perspective of versatility, relatively high strength and ease of preventing warping, as well as heat resistance, the resin film may be a single-layer film selected from the group consisting of a polyethylene film, a polyester-based film, and a polypropylene film, or a laminated film in which two or more films selected from this group are laminated. In the present embodiment, to facilitate extension of the pressure sensitive adhesive sheet, a polyolefin-based film or a vinyl chloride copolymer film of the pressure sensitive adhesive sheet may be used as the resin film serving as the base material 120. Here, the polyolefin-based film according to the present embodiment includes various polyethylene films, various polypropylene films, and an ethylene-based copolymer including ethylene-methacrylic acid copolymer (EMAA). Examples of the vinyl chloride copolymer film that can be used include a vinyl chloride-vinylidene chloride copolymer film, a vinyl chloride-vinyl acetate copolymer film, and a vinyl chloride-ethylene copolymer film.

The thickness of the base material 120 is not particularly limited, but may be preferably 10 μm or more, more preferably 25 μm or more, and even more preferably 40 μm or more, and preferably 500 μm or less, more preferably 200 μm or less, and even more preferably 90 μm or less, from the viewpoint of compatibility between a supporting property and rollability. The thickness of the base material 120 is preferably 10 μm or more and 500 μm or less, more preferably 25 μm or more and 200 μm or less, and even more preferably 40 μm or more and 90 μm or less.

When the pressure sensitive adhesive sheet is stretched, the base material 120 according to the present embodiment is extended in the planar direction simultaneously with the pressure sensitive adhesive layer 110. The base material 120 may be extendable, for example, by 2% or more in the planar direction by stretching the pressure sensitive adhesive sheet. The base material 120 is stretched by stretching the pressure sensitive adhesive sheet, and thus the stretching may be performed in all directions as described above, may be performed in one direction, may be performed in two directions, or may be performed in a plurality of other directions. The base material 120 may be extendable by 2% or more, 8% or more, 15% or more, 30% or more, 50% or more, 80% or more, or 85% or more in the planar direction from the viewpoint of facilitating the stretching of the pressure sensitive adhesive sheet. In addition, the base material 120 may be capable of being extended up to 300%, up to 250%, up to 200%, up to 150%, or up to 120% from the viewpoint of ensuring the minimum hardness at the time of stretching. The extension rate of the base material according to the present embodiment is represented by an increase rate of an area of a surface of the base material during stretching.

The tensile elastic modulus of the base material 120 can be set to preferably 2500 MPa or less, more preferably 2000 MPa or less, even more preferably 1500 MPa or less, and still more preferably 1000 MPa or less, from the viewpoint of ease of elongation during stretching. In addition, the tensile elastic modulus of the base material 120 can be set to preferably 50 MPa or more, more preferably 100 MPa or more, even more preferably 150 MPa or more, still more preferably 300 MPa or more, still even more preferably 350 MPa or more, yet more preferably 500 MPa or more, and yet even more preferably 700 MPa or more, from the viewpoint of controlling the elongation during stretching.

In addition, the elongation percentage of the base material 120 at the time of stretching can be evaluated by, for example, elongation at break. The elongation at break of the base material 120 can be set to preferably 105% or more, more preferably 200% or more, even more preferably 400% or more, and still more preferably 600% or more from the viewpoint of ease of elongation at the time of stretching. In addition, the elongation at break of the base material 120 may be preferably 1500% or less, more preferably 1200% or less, even more preferably 1000% or less, and still more preferably 800% or less, from the viewpoint of controlling the ease of elongation at the time of stretching.

### Release Sheet

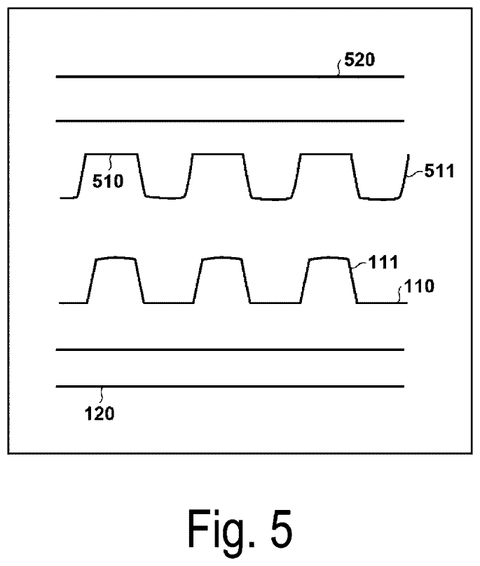

In addition, the pressure sensitive adhesive sheet according to the present embodiment may include a release sheet which is in contact with the pressure sensitive adhesive layer 110 and has an uneven surface complementary to the uneven surface of the pressure sensitive adhesive layer 110. The release sheet has a release layer 510. FIG. 5 is a side view illustrating a shape of the release layer 510 relative to the pressure sensitive adhesive layer 110 according to the present embodiment.

As described above, the release layer 510 has the uneven surface complementary to the uneven surface of the pressure sensitive adhesive layer 110. That is, a pitch P and a height of each of protrusions 511 in the release layer 510 are the same as those of the protrusions 111. Here, the protrusions 511 may each have the same shape as the recess of the pressure sensitive adhesive layer 110, or may have a width and a diameter different from those of the recess of the pressure sensitive adhesive layer 110. In the present embodiment, the protrusions 111 are arranged in a lattice shape, and the protrusions 511 are arranged in a lattice shape in such a manner that centers of the protrusions 511 are positioned at the centers of the lattice formed by the protrusions 111.

The release sheet may include a base material 520 on a surface that is not in contact with the pressure sensitive adhesive layer 110. The base material 520 can be designed in the same manner as described for the base material 120 of the pressure sensitive adhesive sheet, but need not have the same composition and configuration as the base material 120. For example, the base material 120 of the pressure sensitive adhesive sheet may be EMAA, and the base material 520 of the release sheet may be a polyethylene terephthalate film or the like. In addition, the release sheet may include an undercoat layer (not illustrated) between the release layer 510 and the base material 520.

### Other Layer

The pressure sensitive adhesive sheet may have a layer other than the base material 120 and the pressure sensitive adhesive layer 110. For example, an additional pressure sensitive adhesive layer may be provided on the surface of the base material 120 opposite to the pressure sensitive adhesive layer 110. The pressure sensitive adhesive sheet can be attached to another substrate such as quartz glass via such a pressure sensitive adhesive layer. The type of the additional pressure sensitive adhesive layer is not particularly limited, and for example, the additional pressure sensitive adhesive layer can be formed using a general pressure sensitive adhesive.

### Method for Producing Pressure Sensitive Adhesive Sheet

The method for producing a pressure sensitive adhesive sheet is not particularly limited. For example, the pressure sensitive adhesive sheet in which the pressure sensitive adhesive layer 110 is provided on the base material 120 can be produced as follows. First, an organic solvent is added to the pressure sensitive adhesive composition for forming the pressure sensitive adhesive layer 110 to prepare a solution of the pressure sensitive adhesive composition. Then, the solution is applied on the base material to form a coating film, followed by drying, whereby a pressure sensitive adhesive layer can be provided on the base material 120. Further, a treatment for providing unevenness on the surface of the pressure sensitive adhesive layer is performed, whereby the pressure sensitive adhesive layer 110 having unevenness can be formed.

Examples of the organic solvent to be used for preparing the solution of the pressure sensitive adhesive composition include toluene, ethyl acetate, and methyl ethyl ketone. Examples of the method for applying the solution include a spin coating method, a spray coating method, a bar coating method, a knife coating method, a roll coating method, a roll knife coating method, a blade coating method, a die coating method, a gravure coating method, and a printing method (e.g., a screen printing method and an inkjet method).

The treatment for providing unevenness on the surface of the pressure sensitive adhesive layer is also not particularly limited. For example, unevenness can be provided on the surface of the pressure sensitive adhesive layer by using an imprint method. In the imprint method, it is possible to use a mold whose surface has a shape complementary to the unevenness to be provided. Specifically, unevenness can be provided on the surface of the pressure sensitive adhesive layer by heating the pressure sensitive adhesive layer provided on the base material while pressing the pressure sensitive adhesive layer with the mold. As a more specific method, the pressure sensitive adhesive layer is pressed with a mold, the pressure sensitive adhesive layer is heated and maintained for a predetermined time, then the pressure sensitive adhesive layer is cooled, and the mold can be removed. When the pressure sensitive adhesive layer is heated, for example, the pressure sensitive adhesive layer can be heated to a temperature higher than the softening point of the pressure sensitive adhesive layer. In addition, the time for which the pressure sensitive adhesive layer is maintained in a heated state is not particularly limited. For example, the pressure sensitive adhesive layer in the heated state may be maintained for 10 seconds or longer, or may be maintained for 10 minutes or shorter. As a specific method for heating the pressure sensitive adhesive layer while pressing the pressure sensitive adhesive layer with the mold, there is a method of vacuum laminating the pressure sensitive adhesive layer provided on the base material and the mold. Note that the pressure sensitive adhesive layer 110 having a surface with unevenness may be formed on the base material by a single stage step, instead of a two-stage step of formation of the pressure sensitive adhesive layer and formation of unevenness.

As another method, the pressure sensitive adhesive layer 110 having an uneven shape can be provided by spray coating of the solution of the pressure sensitive adhesive composition. Furthermore, the pressure sensitive adhesive layer 110 having a rough surface or a fibrous surface can be provided by adding a filler to the solution of the pressure sensitive adhesive composition and applying such a solution. As still another method, the pressure sensitive adhesive layer having an uneven shape can be provided directly on the base material by applying the solution of the pressure sensitive adhesive composition in accordance with a desired pattern using a printing method such as an inkjet method.

A pressure sensitive adhesive sheet having no base material 120 can be prepared by forming the pressure sensitive adhesive composition into a sheet. Furthermore, the pressure sensitive adhesive layer may be formed by applying a liquid pressure sensitive adhesive containing the pressure sensitive adhesive composition to an arbitrary object. In these cases, after the pressure sensitive adhesive layer is formed, the surface of the pressure sensitive adhesive layer may be subjected to the treatment for providing unevenness, or the pressure sensitive adhesive layer may be formed by a method in which unevenness is formed on the surface.

Method for producing electronic component or semiconductor device using pressure sensitive adhesive sheet according to present embodiment The pressure sensitive adhesive sheet according to the present embodiment as described above can be used for holding an element separated from a holding substrate. For example, the pressure sensitive adhesive sheet can be used as a die catch sheet for catching a die such as a semiconductor die. The element is used for producing an electronic component or a semiconductor device. That is, such a pressure sensitive adhesive sheet can be used in the production of an electronic component or a semiconductor device.

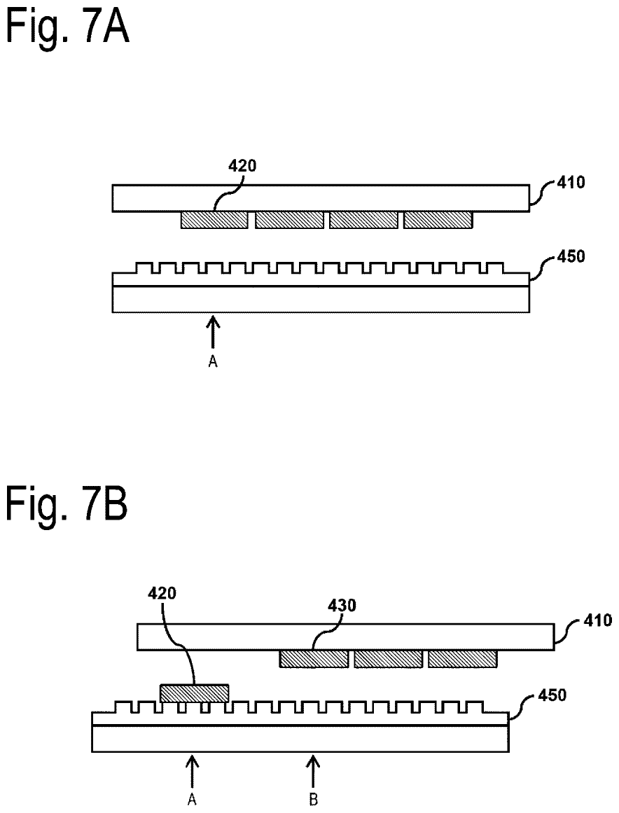

A method for producing an electronic component or a semiconductor device according to the present embodiment includes a step of separating an element from a holding substrate, a step of deforming a protrusion of a pressure sensitive adhesive layer to hold the element on the pressure sensitive adhesive sheet, and a step of restoring the protrusion to a protruding shape to promote separation of the element from the pressure sensitive adhesive sheet. The element held on the pressure sensitive adhesive sheet may be subjected to an additional treatment to produce an electronic component or a semiconductor device. Hereinafter, such a method for producing an electronic component or a semiconductor device will be described in detail with reference to a flowchart of FIG. 6, schematic diagrams illustrating separation and capture of an element in FIGS. 7A and 7B, and schematic diagrams illustrating extension (stretching) of a pressure sensitive adhesive sheet in FIGS. 8A and 8B.

### s10: Preparation of Holding Substrate

In step S10 illustrated in FIG. 6, a holding substrate to which an element is attached is prepared. The type of the element is not particularly limited. The element may be, for example, a semiconductor chip such as an LED chip, a semiconductor chip with a protective film, a semiconductor chip with a die attach film (DAF), or the like. In addition, the element may be a micro light-emitting diode, a mini light-emitting diode, a power device, micro electro mechanical systems (MEMS), or a controller chip, or may be a constituent element thereof. The element may be a singulated product such as a wafer, a panel, or a substrate. The element may have a circuit surface on which an integrated circuit having circuit elements such as a transistor, a resistor, and a capacitor is formed. Alternatively, the element is not necessarily limited to a singulated product, and may be various wafers, various substrates, or the like which are not singulated.

The size of the element is not particularly limited. The size of the element may be, for example, preferably 100 μm² or more, more preferably 500 μm² or more, and even more preferably 1000 μm² or more. On the other hand, the size of the element may be preferably 100 mm² or less, more preferably 25 mm² or less, and even more preferably 1 mm² or less. In a case where a small-sized element is used, a laser lift-off method to be described below is suitable for separating the element because it is easy to selectively separate a small element.

Examples of the wafer include semiconductor wafers such as a silicon wafer, a silicon carbide (SiC) wafer, and a compound semiconductor wafer (e.g., a gallium phosphide (GaP) wafer, a gallium arsenide (GaAs) wafer, an indium phosphide (InP) wafer, and a gallium nitride (GaN) wafer). The size of the wafer is not particularly limited, but is preferably 6 inches (about 150 mm in diameter) or more and more preferably 12 inches (about 300 mm in diameter) or more. Note that the shape of the wafer is not limited to a circle and may be, for example, a quadrangle shape, such as a square or a rectangle.

Examples of the panel include a fan-out type semiconductor package (for example, FOWLP or FOPLP). That is, a treatment target may be a semiconductor package before or after singulation in a fan-out type semiconductor package production technique. The size of the panel is not particularly limited, but may be, for example, a quadrangle substrate having a size of about 300 to 700 mm.

Examples of the substrate include a glass substrate, a sapphire substrate, and a compound semiconductor substrate.

The type of the holding substrate is also not particularly limited. For example, the holding substrate may be a pressure sensitive adhesive sheet or a tray. The pressure sensitive adhesive sheet may have a pressure sensitive adhesive layer, and this pressure sensitive adhesive layer may be provided on a base material. In this case, the holding substrate can hold an element on the pressure sensitive adhesive layer. The base material may be a resin film or a rigid substrate.

A method for preparing such a holding substrate for holding an element is not particularly limited. For example, a semiconductor wafer can be attached onto the holding substrate, and then the semiconductor wafer can be diced. Thus, an element can be obtained by dicing the semiconductor wafer, and the holding substrate to which the element is attached can be obtained.

As another method, an element obtained by dicing a semiconductor wafer is transferred to a holding substrate, thereby obtaining the holding substrate to which the element is attached. For example, after the semiconductor wafer held on the wafer substrate is diced, the obtained element can be brought into close contact with the pressure sensitive adhesive layer of the holding substrate. Thereafter, when an external stimulus such as laser light is applied, the adhesion between the wafer substrate and the element can be lowered. By such a step, the element can be transferred from the wafer substrate to the holding substrate.

Note that as will be described below, in one embodiment, the element is separated from the holding substrate by irradiation with laser light (laser lift-off method). In a case where such a method is used, the pressure sensitive adhesive layer of the holding substrate can contain a laser light absorber. Examples of the laser light absorber include one or more selected from a pigment and a dye.

### s20: Separation of Element

In step S20 illustrated in FIG. 6, the element attached to the holding substrate is separated from the holding substrate by an external stimulus. Specifically, the element is relatively separated from the holding substrate. In addition, the element relatively approaches the pressure sensitive adhesive sheet. When the element and the pressure sensitive adhesive layer of the pressure sensitive adhesive sheet come into contact with each other, the element is separated from the holding substrate and captured on the pressure sensitive adhesive sheet. The type of the external stimulus is not particularly limited, and examples thereof include energy application, cooling, stretching of the holding substrate, and a physical stimulus (for example, pressing of the back surface of the holding substrate using a pin or the like). When one or more of these external stimuli are used, the bonding force between the holding substrate and the element can be reduced to separate the element from the holding substrate.

In the present embodiment, capturing of the element in step S30 can be performed in such a manner that the relative arrangement of a plurality of elements on the holding substrate is different from the relative arrangement of a plurality of elements on the pressure sensitive adhesive sheet. Thus, in step S20, it is possible to selectively apply an external stimulus to some of the plurality of elements attached to the holding substrate or to the attachment site of the elements on the holding substrate.

Examples of the method for applying energy include local heating, light irradiation, and heat ray irradiation. Examples of the light irradiation method include infrared irradiation, visible light irradiation, and laser light irradiation. Preferably, laser light irradiation is performed as the external stimulus, that is, separation of the element from the holding substrate is performed by a laser lift-off method. In this case, the laser light is irradiated toward the attachment site of a specific element on the holding substrate. For example, such irradiation with laser light can be performed from the surface of the holding substrate on the side opposite to the element. Then, gas is generated at a contact site between the specific element and the holding substrate. For example, when the laser light is absorbed by the pressure sensitive adhesive layer, gas is generated by sublimation of at least a part of the pressure sensitive adhesive layer. When at least a part of the pressure sensitive adhesive layer is sublimated as described above, the adhesion area between the specific element and the pressure sensitive adhesive layer is reduced, and thus the adhesive force between the specific element and the holding substrate is reduced. In addition, pressure of the generated gas also reduces the adhesive force between the specific element and the holding substrate. As a result, the specific element is separated from the holding substrate.

Irradiation conditions of the laser light are not particularly limited. From the viewpoint of selectively and efficiently separating some elements, the frequency of the laser light is preferably 10000 Hz or more and 100000 Hz or less. A beam diameter of the laser light is preferably 10 μm or more, and more preferably 20 μm or more, and preferably 100 μm or less, and more preferably 40 μm or less. The output of the laser light is preferably 0.1 W or more and 10 W or less. The scanning speed of the laser light is preferably 50 mm/second or more and 2000 mm/second or less.

### s30: Capture of Element

In step S30, the element separated from the holding substrate is captured on the pressure sensitive adhesive sheet. Specifically, the element is relatively separated from the holding substrate. In addition, the element relatively approaches the pressure sensitive adhesive sheet. When the element and the pressure sensitive adhesive layer of the pressure sensitive adhesive sheet come into contact with each other, the element is captured on the pressure sensitive adhesive sheet.

As illustrated in FIG. 7A, a separated element 140a is captured at a position (P1) on the pressure sensitive adhesive sheet 150 by positioning the position (P1) on the pressure sensitive adhesive sheet 150 to face the element 140a attached to the holding substrate 130. Further, as illustrated in FIG. 7B, a separated element 140b is captured at a position (P2) on the pressure sensitive adhesive sheet 150 by positioning the position (P2) on the pressure sensitive adhesive sheet 150 to face the element 140b attached to the holding substrate 130. In this way, it is possible to separate and capture an element while changing the relative position between the holding substrate and the pressure sensitive adhesive sheet in the planar direction. Thus, elements can be positioned in such a manner that the relative arrangement of a plurality of elements on the holding substrate is different from the relative arrangement of a plurality of elements on the pressure sensitive adhesive sheet. However, as already explained, in a case where a pressure sensitive adhesive sheet having a flat surface is used, the component 140a may be captured at a position deviating from the position (P1) in the example of FIG. 7A due to pressure generated between the element and the pressure sensitive adhesive sheet. However, when the surface of the pressure sensitive adhesive layer has unevenness, the pressure generated between the element and the pressure sensitive adhesive layer is alleviated, and thus it becomes easier to capture the element at a desired position on the pressure sensitive adhesive sheet.

In one embodiment, the holding substrate and the pressure sensitive adhesive sheet are stationary, and the element separated from the holding substrate moves to the pressure sensitive adhesive sheet. For example, in a case where the laser lift-off method is used, the element can be moved toward the pressure sensitive adhesive sheet by the pressure of the gas generated by the irradiation with laser light. On the other hand, it is not essential for the element to move. For example, the holding substrate may be moved away from the element. Alternatively, the pressure sensitive adhesive sheet may be moved to approach the element.

### s40: Treatment of Element

In step S40 illustrated in FIG. 6, a treatment for producing an electronic component or a semiconductor device is performed using the element held on the pressure sensitive adhesive sheet. The treatment for producing an electronic component or a semiconductor device is not particularly limited, and examples thereof include transferring an element held on a pressure sensitive adhesive sheet to a wiring substrate. The wiring substrate may be provided with wiring connected to the element. In this case, the position of each element on the wiring substrate is predetermined. Thus, in step S20, a plurality of elements can be captured on the pressure sensitive adhesive sheet to be arranged to coincide with the relative arrangement between a plurality of elements on the wiring substrate. Thereafter, the wiring substrate is bonded to surfaces of the plurality of elements on the side opposite to the pressure sensitive adhesive sheet. Thereafter, in next step S50, separation of elements is promoted and the elements are separated from the pressure sensitive adhesive sheet.

### s50: Separation of Elements

In step S50 illustrated in FIG. 6, the elements held on the pressure sensitive adhesive sheet are separated. In the present embodiment, when the pressure sensitive adhesive sheet is stretched, the surface peeling force at the time of separating an element can be reduced. As illustrated in FIG. 8A, elements 140a to 140d are held on the pressure sensitive adhesive sheet 150. In addition, FIG. 8B is a diagram illustrating the pressure sensitive adhesive sheet when stretching is performed from the state of FIG. 8A. Here, for example, a portion of the pressure sensitive adhesive layer on the side opposite to a portion on which the element is held is placed on the pedestal 310, and a peripheral portion 320 (ring frame) of the pressure sensitive adhesive sheet is pressed down as indicated by an arrow (P3) at a temperature of −20° C. or higher and 80° C. or lower, whereby the pressure sensitive adhesive sheet 150 can be stretched.

Thereafter, the plurality of elements 140a to 140d are separated from the pressure sensitive adhesive sheet 150. By the stretching, the pitch P of the protrusions 111 for capturing the elements is enlarged, and the surface peeling force of the elements by the pressure sensitive adhesive layer 110 is reduced, and thus these elements can be more easily picked up from the pressure sensitive adhesive sheet. Accordingly, the elements can be separated from the pressure sensitive adhesive sheet 150 by bringing the elements in a stretched state into contact with a transfer destination and pulling the transfer destination away from the pressure sensitive adhesive sheet without applying any other external stimulus. By such a procedure, an electronic component or a semiconductor device having an element (for example, a semiconductor element) can be produced.

Note that although the description is given here assuming that the separation of the elements is performed without applying an external stimulus other than the stretching of the pressure sensitive adhesive sheet 150 in S50, another different external stimulus may be applied for the separation of the elements. As the external stimulus, any external stimulus that can be applied to the holding substrate in S20, such as application of energy, can be applied to the pressure sensitive adhesive sheet 150.

### EXAMPLES

Hereinafter, the present invention will be described in further detail through presentation of examples. However, the present invention is in no way limited to the following examples. Parts and % in each example are on a mass basis unless otherwise specified.

In Examples and Comparative Examples, the following compounds were used.

### Component (A)

Energy ray-curable resin (A1): SBS having a vinyl group in a side chain (styrene-butadiene-styrene block copolymer (SBS) having a 1,2-vinyl group in a side chain [copolymer having a branched structure and having a radial structure including a branching point as a core; number average molecular weight (Mn): 160000; mass average molecular weight (Mw): 180000; the content of the styrene block was 20 mass %; the content of the butadiene block was 80 mass %; the content of the constituent unit having a 1,2-vinyl group in a side chain was 42 mol % in all constituent units constituting the butadiene block; melt flow rate measured at a temperature of 200° C. and a load of 5 kg: 5 g/10 min])
Energy ray-curable resin (A2): PB having a vinyl group in a side chain (polybutadiene copolymers having a 1,2-vinyl group in a side chain [mass average molecular weight (Mw): 5500; glass transition temperature: −49° C.; liquid at room temperature])

### Component (C)

Photopolymerization initiator (C1): bis(2,4,6-trimethylbenzoyl)phenylphosphine oxide

### Antioxidant (E)

Antioxidant (E1): mixture of a hindered phenol-based antioxidant and a phosphorus-based antioxidant in mass ratio of 1:1

### Example 1

A pressure sensitive adhesive composition was prepared by dissolving 100 parts by mass of the energy ray-curable resin (A1), 50 parts by mass of the energy ray-curable resin (A2), 3 parts by mass of the photopolymerization initiator (C1), and 3 parts by mass of the antioxidant (E1) in toluene. This pressure sensitive adhesive composition was applied onto a release-treated face of a release sheet (available from LINTEC Corporation, trade name: SP-PET381130, product in which a silicone-based releasing agent is layered on a polyethylene terephthalate film, thickness: 38 μm), and the obtained coating film was dried at 100° C. for 2 minutes to form a pressure sensitive adhesive layer having a thickness of 25 μm. Onto the pressure sensitive adhesive layer, a non-embossed face of an EMAA base material (ethylene-methacrylic acid copolymer film, acid content: 9 mass %, available from Riken Technos Corp., a product in which one surface is satin-finished by embossing, thickness: 80 μm, elongation at break: 490%) was bonded to prepare a pressure sensitive adhesive sheet.

After the release sheet was peeled off, the pressure sensitive adhesive layer of the pressure sensitive adhesive sheet was bonded to a replica mold in which a recess shape was formed in advance, followed by vacuum lamination at 60° C. for 300 seconds. Then, ultraviolet rays were irradiated at an illuminance of 200 mW/cm² and a light amount of 800 mJ/cm² using an ultraviolet irradiator (available from Heraeus) to prepare a pressure sensitive adhesive sheet having a surface with an uneven shape.

The uneven shape of the pressure sensitive adhesive layer of the pressure sensitive adhesive sheet was a shape in which pillars were arranged in a lattice shape as in FIG. 2A. The pitch P between the pillars in the pressure sensitive adhesive sheet was 20 μm. The height (H) of each pillar illustrated in FIG. 4A was 8 μm, the tip diameter (T) was 8 μm, and the base diameter (D) was 16 μm. In addition, a ratio of the area of the bonding portion between the pressure sensitive adhesive layer and the element to be captured (that is, the area of the tip surface of the protrusion) relative to the area of the pressure sensitive adhesive sheet was about 12.6%. Note that the replica mold used had a surface shape complementary to such an uneven shape.

### Tensile Elastic Modulus of Base Material

Note that in the present examples, the base material used in the examples was cut into 150 mm in an MD direction×15 mm in a TD direction to obtain a test sample. The test sample was measured for the tensile elastic modulus in an environment of 23° C. and 50% RH (relative humidity) in accordance with JIS K 7161-1:2014 and JIS K 7127:1999. Specifically, a tensile test was performed on the test sample using a tensile tester (product name “Autograph (trade name) AG-IS 500N”, available from Shimadzu Corporation) at a speed of 200 mm/min after setting a distance between chucks set to 100 mm, and the tensile elastic modulus (MPa) in the MD direction of the backing was measured. In the present example, the measured tensile elastic modulus of the base material was 165 MPa.

Note that MD in the MD direction is an abbreviation for the machine direction, and for example, the MD direction of the base material means the longitudinal direction at the time of producing the base material. In addition, TD in the TD direction is an abbreviation for the transverse direction, and for example, the TD direction of the base material means the width direction at the time of producing the base material.

### Example 2

A pressure sensitive adhesive sheet was prepared in the same manner as in Example 1, except that the amount of the energy ray-curable resin (A2) was 75 parts by mass.

### Comparative Examples 1 and 2

Pressure sensitive adhesive sheets were prepared in the same manner as in Example 1 and Example 2 except that the bonding of the replica mold and the pressure sensitive adhesive layer and the vacuum lamination were not performed, and were referred to as Comparative Example 1 and Comparative Example 2, respectively. In these Comparative Examples, unevenness was not formed on the surface of the pressure sensitive adhesive layer.

### Measurement of Shear Storage Elastic Modulus

Pressure sensitive adhesive layers were formed of the pressure sensitive adhesive compositions obtained in Examples and Comparative Examples, and were irradiated with ultraviolet rays at an illuminance of 200 mW/cm² and a light amount of 800 mJ/cm² using an ultraviolet irradiator (available from Heraeus) to prepare sensitive adhesive layers each having a thickness of 1 mm. Each of the obtained pressure sensitive adhesive layers was punched into a circular column shape having a diameter of 8 mm, and a viscoelasticity measurement apparatus (available from Anton Paar, product name: “MCR302”) was used to measure a shear storage elastic modulus of the pressure sensitive adhesive layer at 23° C. by a torsional shear method under conditions of a test start temperature of −60° C., a test end temperature of 150° C., a temperature increase rate of 3.5° C./min, and a frequency of 1 Hz.

### Preparation of Sample for Surface Peeling Force Measurement

The pressure sensitive adhesive layer of the pressure sensitive adhesive sheet obtained in each of Examples was attached to a ring frame (made of stainless steel), and the pressure sensitive adhesive sheet was cut in accordance with the outer diameter of the ring frame.

A wafer substrate (mirror silicone wafer, 6 inches, 150 μm thick) was fixed to a separately prepared dicing tape and diced into a square of 10 mm×10 mm to obtain a plurality of elements (silicon chip, the element had a size of 10 mm×10 mm×150 μm). The obtained plurality of elements were attached to the central portion of the inner side of the ring frame of the pressure sensitive adhesive layer of the pressure sensitive adhesive sheet, and the dicing tape was peeled off to transfer the elements from the dicing tape to the pressure sensitive adhesive sheet. At this time, the surface was adjusted in such a manner that the mirror surface of the silicon chip was attached to the pressure sensitive adhesive layer of the pressure sensitive adhesive sheet, and the attachment was performed by lamination at room temperature (23° C.) to prepare a sample for surface peeling force measurement composed of the pressure sensitive adhesive sheet on which the element was mounted and which was supported by a ring frame.

### Surface Peeling Force Before Stretching

A push-pull gauge (available from Aikoh Engineering Co., Ltd., product name “RX-5”) was used for the obtained sample for surface peeling force measurement. The element was pushed through the pressure sensitive adhesive sheet with a needle, and the force required to peel the element from the pressure sensitive adhesive sheet was read from the push-pull gauge and taken as the surface peeling force.

Surface Peeling Force after Stretching

The obtained sample for surface peeling force measurement was placed in an expanding apparatus having a mechanism illustrated in FIGS. 8A and 8B, and the ring frame was pushed down under the conditions of a speed of 1 mm/sec and pull-down amounts of 5 mm and 10 mm in a state where the element was supported by the pedestal 310 through the pressure sensitive adhesive sheet. After the push-down, a push-pull gauge (available from Aikoh Engineering Co., Ltd., product name “RX-5”) was used. The element was pushed with a needle through the pressure sensitive adhesive sheet, and the force required for peeling the element from the pressure sensitive adhesive sheet was read from the push-pull gauge and taken as the surface peeling force.

Table 1 shows the evaluation results of the shear storage elastic modulus and the surface peeling force of Examples 1 and 2 and Comparative Examples 1 and 2.

TABLE 1

| | | Surface peeling force [N] | | |
|---|---|---|---|---|
| | Shear storage | | After stretching | After stretching |
| | elastic modulus | Before | (Pull-down | (Pull-down |
| | [MPa] | stretching | amount 5 mm) | amount 10 mm) |
| Example 1 | 0.38 | 3.07 | 2.25 | 1.62 |
| Example 2 | 0.25 | 4.39 | 3.36 | 2.07 |
| Comparative | 0.38 | 4.10 | 4.02 | 3.87 |
| Example 1 | | | | |
| Comparative | 0.25 | 4.50 | 4.38 | 4.44 |
| Example 2 | | | | |

In the pressure sensitive adhesive sheets of Examples 1 and 2 in which the pressure sensitive adhesive layer was provided with unevenness, the surface peeling force was reduced by stretching with a pull-down amount of 5 mm, and the surface peeling force was further reduced by stretching with a pull-down amount of 10 mm, which indicates that the element was easily peeled. On the other hand, in the pressure sensitive adhesive sheets of Comparative Example 1 and Comparative Example 2 in which the pressure sensitive adhesive layer was not provided with unevenness, almost no facilitation of peeling of the element was observed in any of the stretching in which the pull-down amount was 5 mm and the stretching in which the pull-down amount was 10 mm. As described above, it has been confirmed that with a configuration in which the number of protrusions where the pressure sensitive adhesive layer and the element are in contact with each other is reduced by stretching the pressure sensitive adhesive sheet, the adhesion area between the pressure sensitive adhesive layer and the element is reduced, which can contribute to a reduction in the surface peeling force. According to such facilitation of peeling of the element, it is possible to omit an external stimulus for picking up such as pressing by a needle or energy application when an element is peeled, and it is possible to reduce damage to the element and other members.

Although the embodiments of the invention have been described above, the invention is not limited to the above-described embodiments, and various modifications and changes can be made within the scope of the gist of the invention.

This application claims priority based on Japanese Patent Application No. 2022-151756 filed on Sep. 22, 2022, Japanese Patent Application No. 2022-151757 filed on Sep. 22, 2022, Japanese Patent Application No. 2023-058459 filed on Mar. 31, 2023, Japanese Patent Application No. 2023-058460 filed on Mar. 31, 2023, Japanese Patent Application No. 2023-058462 filed on Mar. 31, 2023, and Japanese Patent Application No. 2023-058463 filed on Mar. 31, 2023, the entire contents of which are incorporated herein by reference.

### REFERENCE SIGNS LIST

110: Pressure sensitive adhesive layer, 111: Protrusion, 120: Base material, 130: Holding substrate, 140a, 140b, 140c, 140d: Element, 150: Pressure sensitive adhesive sheet, 310: Pedestal, 320: Ring frame, 510: Release layer, 511: Protrusion, 520: Base material

1. A method of peeling an object from a pressure sensitive adhesive sheet, the method comprising:
stretching a pressure sensitive adhesive sheet in a planar direction, the pressure sensitive adhesive sheet including a pressure sensitive adhesive layer having a surface with unevenness, and holding an object on the pressure sensitive adhesive layer; and
peeling the object from the pressure sensitive adhesive layer of the pressure sensitive adhesive sheet stretched in the planar direction.

2. The peeling method according to claim 1, wherein the peeled object is transferred to a transfer destination different from the pressure sensitive adhesive sheet.

3. The peeling method according to claim 2, characterized in that the peeling is performed by bringing the object held by the pressure sensitive adhesive sheet stretched in the planar direction into contact with the transfer destination, and separating the transfer destination from the pressure sensitive adhesive sheet without applying an external stimulus to the pressure sensitive adhesive sheet.

4. The peeling method according to claim 1, wherein
the pressure sensitive adhesive sheet further includes a base material that supports the pressure sensitive adhesive layer, and
the base material has a tensile elastic modulus of 2500 MPa or less.

5. The peeling method according to claim 4, wherein the base material has an elongation at break of 105% or more.

6. The peeling method according to claim 4, wherein the base material is a polyolefin-based film or a vinyl chloride copolymer film.

7. The peeling method according to claim 1, wherein in the stretching, the pressure sensitive adhesive sheet is stretched by 1% or more in the planar direction.

8. The peeling method according to claim 1, wherein the pressure sensitive adhesive layer has a plurality of protrusions separated from each other with a boundary defined by a recess, and a pitch of the plurality of protrusions in the pressure sensitive adhesive sheet before stretching is 1 μm or more and 100 μm or less.

9. The peeling method according to claim 8, wherein a pitch of the protrusions of the pressure sensitive adhesive sheet after stretching is 1.05 times or more the pitch of the protrusions before stretching.

10. The peeling method according to claim 1, wherein in the stretching, the pressure sensitive adhesive sheet is stretched by displacing an inner side of a peripheral portion of the pressure sensitive adhesive sheet in a thickness direction of the pressure sensitive adhesive sheet while fixing the peripheral portion of the pressure sensitive adhesive sheet.

11. The peeling method according to claim 1, wherein the pressure sensitive adhesive layer is formed of a pressure sensitive adhesive composition containing an energy ray-curable compound.

12. The peeling method according to claim 1, wherein the pressure sensitive adhesive layer has a shear storage elastic modulus of 0.001 MPa or more and 100 MPa or less.
